(19) United States
(12) Patent Application Publication
(10) Pub. No.: US 2022/0037531 A1
(43) Pub. Date: Feb. 3, 2022

(54) THIN FILM TRANSISTOR AND METHOD FOR MANUFACTURING THE SAME

(71) Applicant: NATIONAL SUN YAT-SEN UNIVERSITY, Kaohsiung (TW)

(72) Inventors: Ting-Chang Chang, Kaohsiung (TW); Yu-Lin Tsai, Kaohsiung (TW); Yu-Ching Tsao, Kaohsiung (TW); Hong-Chih Chen, Kaohsiung (TW); Shin-Ping Huang, Kaohsiung (TW); Mao-Chou Tai, Kaohsiung (TW); Po-Hsun Chen, Kaohsiung (TW)

(21) Appl. No.: 17/017,732

(22) Filed: Sep. 11, 2020

(30) Foreign Application Priority Data
Jul. 28, 2020 (TW) 109125411

(51) Int. Cl. H01L 29/786; H01L 29/24; H01L 29/49; H01L 21/02; H01L 29/66

(52) U.S. Cl. CPC H01L 29/7869; H01L 29/24; H01L 29/4908; H01L 29/78648; H01L 21/02126; H01L 21/0217; H01L 29/66969; H01L 21/02181; H01L 21/02266; H01L 21/02274; H01L 21/02565; H01L 21/0262; H01L 21/02631; H01L 21/02178

(57) ABSTRACT

A thin film transistor is used to solve a problem of low process efficiency of the conventional thin film transistor in preventing hydrogen diffusion. The thin film transistor includes a substrate, multilayer thin films laminated on the substrate, and at least one fluorine-containing thin film laminated in substitution for the multilayer thin films. Each of the multilayer thin films is a gate insulating layer, an active layer, a buffer layer, and a dielectric layer or a protective layer. Each of the at least one fluorine-containing thin film is a fluorine-doped insulating layer, a fluorine-doped active layer, a fluorine-doped buffer layer, and a fluorine-doped dielectric layer or a fluorine-doped protective layer. The invention further discloses a method for manufacturing the thin film transistor.

The application claims the benefit of Taiwan application serial No. 109125411, filed on Jul. 28, 2020, and the entire contents of which are incorporated herein by reference.

### BACKGROUND OF THE INVENTION

### 1. Field of the Invention

The present invention relates to an electronic component, more particularly, to a thin film transistor for improving performance, reliability and production efficiency, and a manufacturing method thereof.

### 2. Description of the Related Art

With the popularity of technology products such as mobile, wearable and miniaturized devices, the research and development requirements for the working performance, miniaturization and durability of electronic components have increased. The metal oxide thin film transistor has the advantages of small volume, low leakage and fast response, high resolution and power saving, and is thus suitable for flexible electronic products with energy saving, light, thin and easy installation and application.

During the manufacturing process of the above-mentioned conventional metal oxide thin film transistor, hydrogen diffusion will occur, and causes the structures such as active layer, insulating layer, buffer layer and dielectric layer of the transistor to be permeated with or to absorb a large amount of hydrogen therebetween, resulting in hydrogen embrittlement which reduces the extensibility, impact resistance and fatigue life of the transistor material. Thus, the transistor material is easy to break suddenly under the action of low intensity stress.

Generally, the process of preventing hydrogen embrittlement is to deposit under low temperature and relatively dry conditions to avoid excessive hydrogen entering the structure of the transistor. In addition, during the annealing process, slow down the cooling rate to prolong the cooling-down time of the transistor, so that hydrogen has enough time to be released from between the layers of the transistor.

In light of this, it is necessary to improve the conventional thin film transistor and its manufacturing method.

### SUMMARY OF THE INVENTION

It is therefore an objective of the present invention to provide a thin film transistor capable of preventing hydrogen diffusion that causes material deterioration.

It is another objective of the present invention to provide a thin film transistor capable of saving power and improving reliability.

It is a further objective of the present invention to provide a method for manufacturing a thin film transistor, which can improve the production efficiency of the transistor.

As used herein, the term “a” or “an” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A thin film transistor of the present invention includes a substrate, multilayer thin films laminated on the substrate, and at least one fluorine-containing thin film laminated in substitution for the multilayer thin films. Each of the multilayer thin films can be a gate insulating layer, an active layer, a buffer layer, a dielectric layer or a protective layer. Each of the at least one fluorine-containing thin film can be a fluorine-doped insulating layer, a fluorine-doped active layer, a fluorine-doped buffer layer, a fluorine-doped dielectric layer or a fluorine-doped protective layer.

The manufacturing method of the thin film transistor of the present invention includes forming multilayer thin films and a plurality of electrodes on a substrate by a vapor deposition, and introducing a fluorine-containing gas during the vapor deposition to form at least one layer of fluorine-containing thin film.

Accordingly, the thin film transistor of the present invention can prevent hydrogen embrittlement by using fluorine-doped material on at least one layer of the thin film transistor to neutralize the hydrogen content infiltrating between the thin films, and adjust the inception voltage to bias to positive voltage, so as to achieve the effect of saving power and improving reliability. Further, in the manufacturing process, by introducing a fluorine-containing gas to neutralize hydrogen in the process of forming each of the thin films of the thin film transistor, the production efficiency can be improved by eliminating the need to prevent hydrogen diffusion through the low-temperature deposition process.

In an example, the material of each of the thin films is silicon dioxide, indium gallium zinc oxide, indium tin zinc oxide, silicon nitride, aluminum oxide or hafnium oxide. In this way, each of the thin films can have various electrical properties, optical characteristics or physical strengths, which has the effect of increasing the applicable range of the thin film transistor.

In an example, the material of the fluorine-containing thin film is silicon dioxide doped with fluorine, indium gallium zinc oxide doped with fluorine, indium tin zinc oxide doped with fluorine, silicon nitride doped with fluorine, aluminum oxide doped with fluorine, or hafnium oxide doped with fluorine. In this way, the doped material can change the energy band structure of the raw material without destroying the nature of the material, which has the effect of maintaining the characteristics of the material.

In an example, the vapor deposition is plasma enhanced chemical vapor deposition or radio frequency magnetron sputtering. In this way, the plasma can increase the reaction rate, which has the effect of improving the process efficiency.

In an example, the fluorine-containing gas is silicon tetrafluoride. In this way, the silicon tetrafluoride gas can form plasma and can also be used as a source of fluoride ions, which has the effect of doping fluorine into the thin film.

### BRIEF DESCRIPTION OF THE DRAWINGS

The present invention will become clearer in light of the following detailed description of illustrative embodiments of this invention described in connection with the drawings.

FIG. 1 is a cross sectional view of a first embodiment of the present invention.

FIG. 2 is a cross sectional view of a second embodiment of the present invention.

FIG. 3 is a variation diagram showing the relationship between drain current and gate voltage of thin film transistors with different fluorine doping ratios according to the present invention.

FIG. 4 is a variation diagram showing the relationship of the thin film transistors shown in FIG. 3 after 1 hour of operation.

In the various figures of the drawings, the same numerals designate the same or similar parts. Furthermore, when the terms “top”, “bottom”, “inner”, “outer”, “side”, and similar terms are used herein, it should be understood that these terms have reference only to the structure shown in the drawings as it would appear to a person viewing the drawings and are utilized only to facilitate describing the invention, rather than restricting the invention.

### DETAILED DESCRIPTION OF THE INVENTION

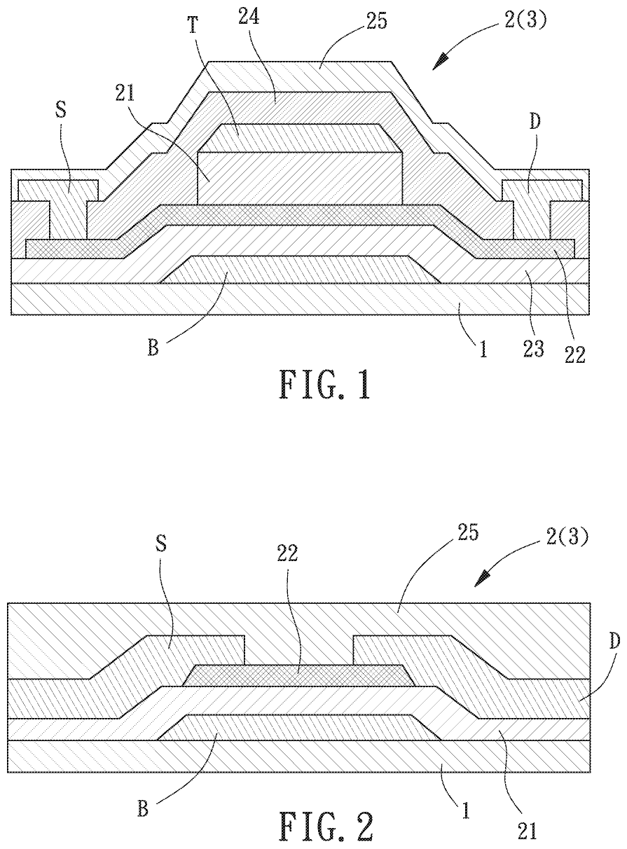

Please refer to FIG. 1, which is a first embodiment of a thin film transistor of the present invention. The thin film transistor includes a substrate 1, multilayer thin films 2 and at least one layer of fluorine-containing thin film 3. The multilayer thin films 2 and the at least one layer of fluorine-containing thin film 3 are located on the substrate 1.

The substrate 1 is used to carry various electronic components, circuits and electrodes. By sputtering, evaporation deposition, laser deposition and other technologies, materials such as metals, semiconductors, and insulation can be formed on the substrate 1 and stacked into a thin film transistor structure. The substrate 1 can be a crystalline material such as silicon wafer, aluminum oxide, aluminum nitride, etc.

The multilayer thin films 2 are laminated on the substrate 1. The multilayer thin films 2 can be various functional structures of transistors such as a gate insulating layer 21, an active layer 22, a buffer layer 23, a dielectric layer 24 and a protective layer 25. The materials of the multilayer thin films 2 include silicon dioxide (SiO₂), indium gallium zinc oxide (IGZO), indium tin zinc oxide (ITZO), silicon nitride (Si3N4), aluminum oxide (Al₂O₃) and hafnium oxide (HfO₂), etc.

The fluorine-containing thin film 3 can be at least one layer of a fluorine-doped insulating layer, a fluorine-doped active layer, a fluorine-doped buffer layer, a fluorine-doped dielectric layer and a fluorine-doped protective layer. The fluorine-containing thin film 3 is laminated with the multilayer thin films 2 that do not contain fluorine (F), so that at least one layer of the thin film transistor is doping with fluorine. The material of the fluorine-containing thin film 3 can be silicon dioxide doped with fluorine (SiO₂:F), indium gallium zinc oxide doped with fluorine (IGZO:F), indium tin zinc oxide doped with fluorine (ITZO: F), silicon nitride doped with fluorine (Si₃N₄:F), aluminum oxide doped with fluorine (Al₂O₃:F) or hafnium oxide doped with fluorine (HfO₂:F), etc. By neutralizing the hydrogen content diffused to the multilayer thin films 2 with fluorine, the material deterioration caused by hydrogen embrittlement can be reduced.

In this embodiment, the thin film transistor further has an upper gate electrode T, a lower gate electrode B, a drain electrode D and a source electrode S. A laminated structure of the gate insulating layer 21, the active layer 22, and the buffer layer 23 can be formed between the upper gate electrode T and the lower gate electrode B. The upper gate electrode T and the lower gate electrode B are respectively insulated from the active layer 22 through the gate insulating layer 21 and the buffer layer 23. Thus, the electric current passing through the active layer 22 is prevented from leaking through the upper gate electrode T and the lower gate electrode B. Moreover, the dielectric layer 24 and the protective layer 25 can cover the upper gate electrode T and the active layer 22. The drain electrode D and the source electrode S are respectively located at both ends of the multilayer thin films 2 and are insulated from the upper gate electrode T and the lower gate electrode B. The thin film transistor is a dual gate transistor, with at least one layer of the multilayer thin films 2 replaced with the fluorine-containing thin film 3. Preferably, the gate insulating layer 21 or the active layer 22 is replaced with a fluorine-doped insulating layer or a fluorine-doped active layer to reduce the hydrogen diffusion and achieve the effect of improving the performance and reliability of the transistor.

Please refer to FIG. 2, which shows a second embodiment of a thin film transistor of the present invention. The lower gate electrode B, the gate insulating layer 21, the active layer 22 and the protective layer 25 are sequentially laminated on the substrate 1. The drain electrode D and the source electrode S are respectively located at both ends of the multilayer thin films 2. The thin film transistor is a bottom gate transistor, and at least one of the gate insulating layer 21 and the active layer 22 can be replaced with the fluorine-containing thin film 3. The thin film transistor of the present invention can be different structural types based on operating conditions and functionality, and the configuration and number of the multilayer thin films 2, the fluorine-containing thin film 3, and the electrodes are not limited to the above-mentioned embodiments.

Please refer to FIG. 1, the method for manufacturing a thin film transistor of the present invention includes forming the lower gate electrode B on the substrate 1 by sputtering; forming the upper gate electrode T on the gate insulating layer 21; forming the drain electrode D and the source electrode S at both ends of the active layer 22; forming the gate insulating layer 21, the buffer layer 23, the dielectric layer 24, and the protective layer 25 by using plasma enhanced chemical vapor deposition (PECVD), and also forming at least one layer of fluorine-doped insulating layer, fluorine-doped buffer layer, fluorine-doped dielectric layer and fluorine-doped protective layer; forming the active layer 22 or the fluorine-doped active layer by radio frequency magnetron sputtering. For example, the gate insulating layer 21 can be a silicon dioxide (SiO₂) thin film produced by the oxidation reaction of methylsilane (SiH₄), and the fluorine-doped insulating layer can be a silicon dioxide doped with fluorine (SiO₂:F) thin film produced by a co-oxidation of methylsilane and silicon tetrafluoride (SiF₄). In addition, the active layer 22 takes indium oxide, gallium oxide and zinc oxide as target materials, and takes oxygen and argon as ion sources, and then controls the ion bombardment of target materials through electric field and magnetic field to diffuse and deposit indium, gallium and zinc atoms to form indium gallium zinc oxide (IGZO) thin film. By adding silicon tetrafluoride as an ion source, indium gallium zinc oxide doped with fluorine (IGZO:F) thin film of the fluorine-doped active layer can be produced. The material and working gas used in the manufacturing method of the thin film transistor of the present invention are not limited to the foregoing embodiments.

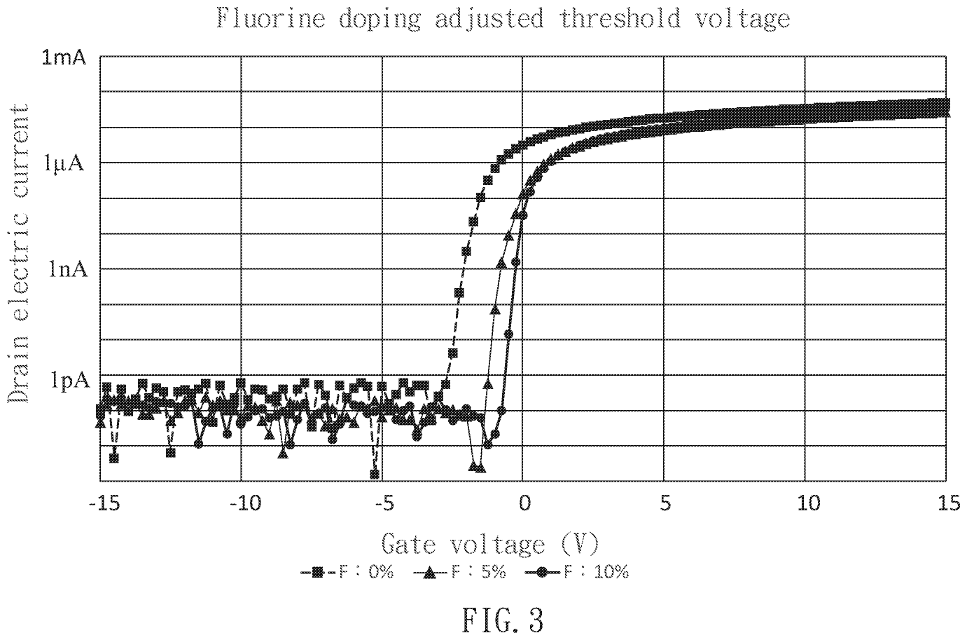

Please refer to FIG. 1 and also FIG. 3, which is a comparison diagram of the fluorine doping ratio of thin film transistor and the corresponding threshold voltage. The threshold voltage is the critical value reached by the gate voltage acting on the active layer 22, which can make the drain current provided by the drain electrode D rise instantaneously, that is, the thin film transistor is in a conducting state. It can be seen from FIG. 3 that the threshold voltage of a thin film transistor without fluorine doping is about minus 2 V, the threshold voltage of 5% fluorine doping ratio is about minus 0.5 V, and the threshold voltage of 10% fluorine doping ratio is close to 0 V. Therefore, the higher the proportion of the fluorine-containing thin film 3 produced by the fluorine doping process in each layer of the thin film transistor, the more positive the threshold voltage of the thin film transistor is, which has the functions of power saving, easy operation and safe use.

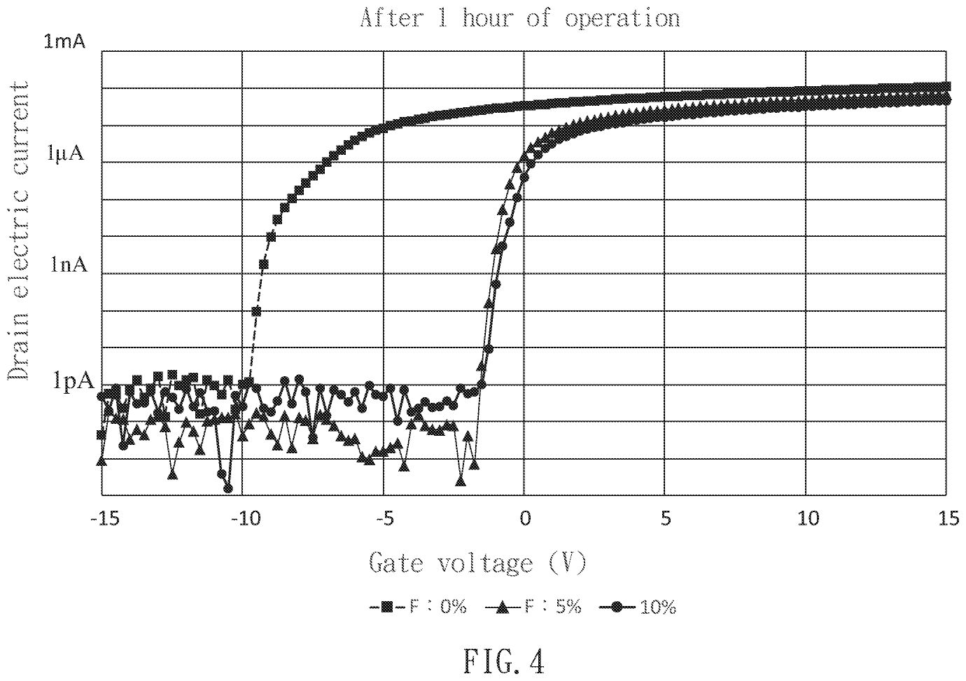

Please refer to FIG. 4, which is a comparison diagram of the threshold voltage of thin film transistor with different fluorine doping ratios after 1 hour of operation. It can be seen from FIG. 4 that the threshold voltage of non-fluorine-doped thin film transistor has shifted to minus 8 V, while the threshold voltages of thin film transistors with 5% and 10% fluorine doping ratios are maintained near 0 V, and there is no obvious shift in the threshold voltage. Therefore, the operation of the thin film transistor with the fluorine-containing thin film 3 is relatively stable, which is not easy to fail in operation, and has the effect of improving reliability.

In summary, the thin film transistor and its manufacturing method of the present invention can prevent hydrogen embrittlement by using fluorine-doped material on at least one layer of the thin film transistor to neutralize the hydrogen content infiltrating between the thin films, and adjust the inception voltage to bias to positive voltage, so as to achieve the effect of saving power and improving reliability. Further, in the method of manufacturing, by introducing a fluorine-containing gas to neutralize hydrogen in the process of forming each of the thin films of the thin film transistor, the production efficiency can be improved without the need to prevent hydrogen diffusion through the low-temperature deposition process.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A thin film transistor, comprising:
a substrate;
multilayer thin films laminated on the substrate, with each of the multilayer thin films being a gate insulating layer, an active layer, a buffer layer, a dielectric layer or a protective layer; and
at least one fluorine-containing thin film laminated in substitution for the multilayer thin films;
wherein each of the at least one fluorine-containing thin film is a fluorine-doped insulating layer, a fluorine-doped active layer, a fluorine-doped buffer layer, a fluorine-doped dielectric layer or a fluorine-doped protective layer.

2. The thin film transistor of claim 1, wherein the material of each of the multilayer thin films is silicon dioxide, indium gallium zinc oxide, indium tin zinc oxide, silicon nitride, aluminum oxide or hafnium oxide.

3. The thin film transistor of claim 1, wherein the material of the at least one fluorine-containing thin film is silicon dioxide doped with fluorine, indium gallium zinc oxide doped with fluorine, indium tin zinc oxide doped with fluorine, silicon nitride doped with fluorine, aluminum oxide doped with fluorine, or hafnium oxide doped with fluorine.

4. A method for manufacturing a thin film transistor, comprising:
forming multilayer thin films and a plurality of electrodes on a substrate by a vapor deposition; and
introducing a fluorine-containing gas during the vapor deposition to form at least one layer of fluorine-containing thin film.

5. The method for manufacturing a thin film transistor of claim 4, wherein the vapor deposition is a plasma enhanced chemical vapor deposition or a radio frequency magnetron sputtering.

6. The method for manufacturing a thin film transistor of claim 4, wherein the fluorine-containing gas is silicon tetrafluoride.
